(19) United States
(12) Patent Application Publication
(10) Pub. No.: US 2026/0223520 A1
(43) Pub. Date: Jul. 30, 2026

(54) METHOD OF MANUFACTURING SOLAR CELL AND SOLAR CELL

(71) Applicant: TOYOTA JIDOSHA KABUSHIKI KAISHA, Toyota-shi (JP)

(72) Inventors: Kohei MATSUNOBU, Toyota-shi (JP); Kenichi OKUMURA, Gotenba-shi (JP); Takashi MABUCHI, Toyota-shi (JP)

(73) Assignee: TOYOTA JIDOSHA KABUSHIKI KAISHA, Toyota-shi (JP)

(21) Appl. No.: 19/416,036

(22) Filed: Dec. 11, 2025

(30) Foreign Application Priority Data
Jan. 24, 2025 (JP) 2025-010485

(51) Int. Cl. H10K 30/82; H10K 30/40; H10K 71/60

(52) U.S. Cl. CPC H10K 30/82; H10K 30/40; H10K 71/60

(57) ABSTRACT

A method of manufacturing a solar cell includes: forming a first carrier transport layer on a first electrode layer of a substrate including the first electrode layer; forming, on the first carrier transport layer, a photoelectric conversion layer that contains an organic-inorganic perovskite compound as a main component; forming a second carrier transport layer on the photoelectric conversion layer; and forming a second electrode layer on the second carrier transport layer. When the first electrode layer is a transparent electrode layer, the method further includes forming a nanoparticle layer by applying a dispersion liquid that contains nanoparticles including the same material as the transparent electrode layer, and when the second electrode layer is a transparent electrode layer, the method further includes forming a nanoparticle layer by applying a dispersion liquid that contains nanoparticles including the same material as the transparent electrode layer.

### CROSS-REFERENCE TO RELATED APPLICATION

This application claims priority to Japanese Patent Application No. 2025-010485 filed on Jan. 24, 2025. The disclosure of the above-identified application, including the specification, drawings, and claims, is incorporated by reference herein in its entirety.

### BACKGROUND

### 1. Technical Field

One aspect of the present disclosure relates to a method of manufacturing a solar cell, and a solar cell.

### 2. Description of Related Art

As one type of a solar cell, there is known a perovskite solar cell in which the main component of a photoelectric conversion layer is a perovskite compound.

As the perovskite solar cell, for example, WO 2017/073472 discloses a perovskite solar cell including a transparent conductive support, an electron blocking layer, a perovskite layer, an electron transport layer, a hole blocking layer, and a back surface electrode. Both the electron blocking layer and the hole blocking layer contain an inorganic material.

### SUMMARY

There is a demand for a method of manufacturing a perovskite solar cell having high energy conversion efficiency that is capable of efficiently converting incident sunlight into electricity.

Therefore, an object of one aspect of the present disclosure is to provide a method of manufacturing a perovskite solar cell having high energy conversion efficiency, and a perovskite solar cell.

The inventors have found that, in the manufacturing of the perovskite solar cell, in a case where nanoparticles including the same material as a transparent electrode layer are disposed on a substrate including the transparent electrode layer as an electrode layer, the energy conversion efficiency of the obtained perovskite solar cell is improved, and thus have completed the one aspect of the present disclosure.

That is, the gist of one aspect of the present disclosure is as follows.
(1) A method of manufacturing a solar cell includes:
forming a nanoparticle layer by applying, onto a transparent electrode layer of a substrate including the transparent electrode layer as a first electrode layer, a dispersion liquid that contains nanoparticles including the same material as the transparent electrode layer;
forming a first carrier transport layer on the nanoparticle layer;
forming, on the first carrier transport layer, a photoelectric conversion layer that contains an organic-inorganic perovskite compound as a main component;
forming a second carrier transport layer on the photoelectric conversion layer; and
forming a second electrode layer on the second carrier transport layer.
(2) A method of manufacturing a solar cell includes:
forming a first carrier transport layer on a first electrode layer of a substrate including the first electrode layer;
forming, on the first carrier transport layer, a photoelectric conversion layer that contains an organic-inorganic perovskite compound as a main component;
forming a second carrier transport layer on the photoelectric conversion layer;
forming a nanoparticle layer by applying, onto the second carrier transport layer, a dispersion liquid that contains nanoparticles including a material that is transparent and conductive; and
forming, as a second electrode layer on the nanoparticle layer, a transparent electrode layer including the same material as the nanoparticle layer.
(3) In the method according to (1) or (2), the transparent electrode layer includes ITO, and an ITO concentration in the dispersion liquid is 2.0% by weight or less with respect to the total weight of the dispersion liquid.
(4) In the method according to (1), the first carrier transport layer is a hole transport layer, and the second carrier transport layer is an electron transport layer.
(5) In the method according to (2), the first carrier transport layer is an electron transport layer, and the second carrier transport layer is a hole transport layer.
(6) A perovskite solar cell includes:
a substrate;
a transparent electrode layer as a first electrode layer on the substrate;
a nanoparticle layer on the transparent electrode layer, the nanoparticle layer including the same material as the transparent electrode layer;
a first carrier transport layer on the nanoparticle layer;
a photoelectric conversion layer on the first carrier transport layer, the photoelectric conversion layer containing an organic-inorganic perovskite compound as a main component;
a second carrier transport layer on the photoelectric conversion layer; and
a second electrode layer on the second carrier transport layer.
(7) A perovskite solar cell includes:
a substrate;
a first electrode layer on the substrate;
a first carrier transport layer on the first electrode layer;
a photoelectric conversion layer on the first carrier transport layer, the photoelectric conversion layer containing an organic-inorganic perovskite compound as a main component;
a second carrier transport layer on the photoelectric conversion layer;
a nanoparticle layer on the second carrier transport layer, the nanoparticle layer including a material that is transparent and conductive; and
a transparent electrode layer as a second electrode layer on the nanoparticle layer, the transparent electrode layer including the same material as the nanoparticle layer.
(8) In the perovskite solar cell according to (6), the first carrier transport layer is a hole transport layer, and the second carrier transport layer is an electron transport layer.
(9) In the perovskite solar cell according to (7), in which the first carrier transport layer is an electron transport layer, and the second carrier transport layer is a hole transport layer.

According to the one aspect of the present disclosure, it is possible to provide a method of manufacturing a perovskite solar cell having high energy conversion efficiency, and a perovskite solar cell.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a schematic cross-sectional view illustrating an example of a structure of a solar cell according to one aspect of the present disclosure;

FIG. 2 is a schematic view showing a perovskite crystal structure;

FIG. 3A is a graph showing a reflectivity of light with respect to incident light in a perovskite solar cell of Comparative Example;

FIG. 3B is a graph showing a transmittance of light with respect to incident light in the perovskite solar cell of Comparative Example;

FIG. 3C is a graph showing an absorbance of light with respect to incident light in the perovskite solar cell of Comparative Example;

FIG. 4 is a graph showing an absorbance of light with respect to incident light in a laminate in which a nanoparticle layer and a hole transport layer are formed, on an ITO film of a substrate, into films in this order;

FIG. 5A is a graph showing an IV evaluation result of the perovskite solar cell of Comparative Example;

FIG. 5B is a graph showing an IV evaluation result of the perovskite solar cell of Comparative Example;

FIG. 5C is a graph showing an IV evaluation result of the perovskite solar cell of Comparative Example;

FIG. 5D is a graph showing an IV evaluation result of the perovskite solar cell of Comparative Example;

FIG. 6A is a graph showing an IV evaluation result of a perovskite solar cell of Example;

FIG. 6B is a graph showing an IV evaluation result of the perovskite solar cell of Example;

FIG. 6C is a graph showing an IV evaluation result of the perovskite solar cell of Example; and

FIG. 6D is a graph showing an IV evaluation result of the perovskite solar cell of Example.

### DETAILED DESCRIPTION OF EMBODIMENTS

Hereinafter, preferred embodiments of one aspect of the present disclosure will be specifically described. In the present specification, features of one aspect of the present disclosure will be described with reference to the drawings as appropriate. In the drawings, dimensions and shapes of each of parts are exaggerated for clarification, and actual dimensions and shapes are not accurately depicted. Therefore, the technical scope of one aspect of the present disclosure is not limited to the dimensions and shapes of each of parts shown in the drawings. The method of manufacturing a solar cell and the solar cell according to one aspect of the present disclosure are not limited to the following embodiments, and can be implemented in various forms in which changes, improvements, and the like appropriate for those skilled in the art are made without departing from the gist of one aspect of the present disclosure.

One aspect of the present disclosure relates to a method of manufacturing a solar cell including a photoelectric conversion layer that contains an organic-inorganic perovskite compound as a main component.

The method of manufacturing a solar cell according to one aspect of the present disclosure includes a step of applying, onto a surface in contact with a transparent electrode layer as a first electrode layer and/or a second electrode layer, a dispersion liquid that contains nanoparticles including the same material as the transparent electrode layer, thereby forming a nanoparticle layer.

In one aspect of the present disclosure, by forming the nanoparticle layer in the step, reflection of incident sunlight at an interface of an electrode layer and a photoelectric conversion layer is suppressed, an amount of the sunlight incident on the photoelectric conversion layer is increased, and as a result, energy conversion efficiency can be improved. That is, a current value of the solar cell can be improved by an effect of reducing reflected light with the nanoparticles in the nanoparticle layer.

### Configuration of Solar Cell

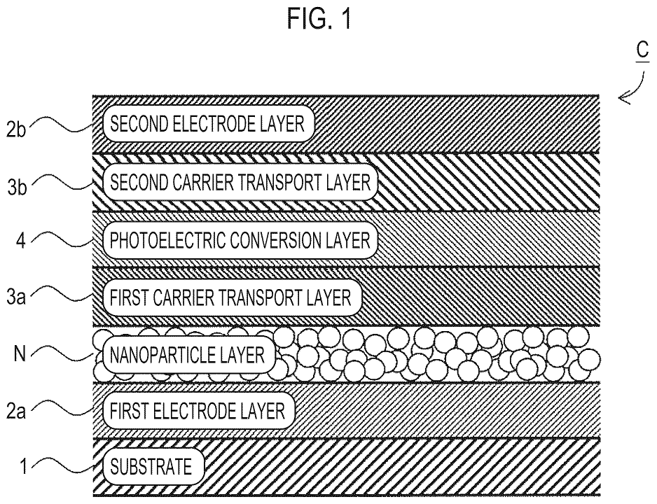

First, a structure of a perovskite solar cell manufactured by the manufacturing method according to one aspect of the present disclosure (hereinafter, also referred to as a solar cell according to one aspect of the present disclosure) will be described in detail. FIG. 1 is a schematic cross-sectional view illustrating an example of the structure of the solar cell according to one aspect of the present disclosure.

As shown in FIG. 1, in one embodiment, a solar cell C according to one aspect of the present disclosure includes a substrate 1, a transparent electrode layer as a first electrode layer 2a, a nanoparticle layer N, a first carrier transport layer 3a, a photoelectric conversion layer 4, a second carrier transport layer 3b, and a second electrode layer 2b in this order. Although not shown in the drawing, in one embodiment, the solar cell according to one aspect of the present disclosure may include a substrate, a first electrode layer, a first carrier transport layer, a photoelectric conversion layer, a second carrier transport layer, a nanoparticle layer, and a transparent electrode layer as a second electrode layer in this order. Although not shown in the drawing, in one embodiment, the solar cell according to one aspect of the present disclosure may include a substrate, a transparent electrode layer as a first electrode layer, a nanoparticle layer, a first carrier transport layer, a photoelectric conversion layer, a second carrier transport layer, a nanoparticle layer, and a transparent electrode layer as a second electrode layer in this order.

Therefore, one embodiment of the present disclosure is a perovskite solar cell including: a substrate; a first electrode layer on the substrate; a first carrier transport layer on the first electrode layer; a photoelectric conversion layer on the first carrier transport layer, the photoelectric conversion layer containing an organic-inorganic perovskite compound as a main component; a second carrier transport layer on the photoelectric conversion layer; and a second electrode layer on the second carrier transport layer, in which the substrate is a transparent substrate, in a case where the first electrode layer is a transparent electrode layer, the perovskite solar cell further includes, between the first electrode layer and the first carrier transport layer, a nanoparticle layer including the same material as the transparent electrode layer, and in a case where the second electrode layer is a transparent electrode layer, the perovskite solar cell further includes, between the second carrier transport layer and the second electrode layer, a nanoparticle layer including the same material as the transparent electrode layer. In the embodiment, in a case where the first electrode layer is a transparent electrode layer, the first carrier transport layer may be a hole transport layer and the second carrier transport layer may be an electron transport layer; in a case where the second electrode layer is a transparent electrode layer, the second carrier transport layer may be a hole transport layer and the first carrier transport layer may be an electron transport layer; and in a case where both the first electrode layer and the second electrode layer are transparent electrode layers, one of the first carrier transport layer and the second carrier transport layer may be a hole transport layer and the other may be an electron transport layer.

### Nanoparticle Layer N

The nanoparticle layer N is a layer located at an intermediate portion of the transparent electrode layer as the first electrode layer 2a and the first carrier transport layer 3a, and/or at an intermediate portion of the transparent electrode layer as the second electrode layer 2b and the second carrier transport layer 3b. The nanoparticle layer N is composed of nanoparticles including the same material that is transparent and conductive as a material that is transparent and conductive, the material being used for forming the transparent electrode layer as the first electrode layer 2a and/or the second electrode layer 2b (also simply referred to as “nanoparticles” in the present specification and the like). The nanoparticle layer N suppresses reflection of sunlight incident on the solar cell C at an interface of the first electrode layer 2a and the photoelectric conversion layer 4 and/or at an interface of the second electrode layer 2b and the photoelectric conversion layer 4.

More specifically, the sunlight incident on the solar cell C is suppressed from being reflected toward the outside at the interface of the first electrode layer 2a and the photoelectric conversion layer 4 and/or at the interface of the second electrode layer 2b and the photoelectric conversion layer 4 by the nanoparticle layer N (that is, the reflection of the incident sunlight), and is likely to be transmitted toward the photoelectric conversion layer 4.

The material of the nanoparticle layer N includes the same material as the transparent electrode layer as the first electrode layer and/or the second electrode layer that is in contact with the nanoparticle layer N. Therefore, the nanoparticle layer N can be changed by the first electrode layer and/or the second electrode layer described later.

An average particle diameter of the nanoparticles in the nanoparticle layer N is usually 500 nm or less, in one embodiment 400 nm or less, in one embodiment 300 nm or less, in one embodiment 200 nm or less, in one embodiment 100 nm or less, in one embodiment 80 nm or less, in one embodiment 60 nm or less, in one embodiment 40 nm or less, and in one embodiment 20 nm or less. The lower limit value of the average particle diameter of the nanoparticles in the nanoparticle layer N is not limited. The average particle diameter of the nanoparticles in the nanoparticle layer N is usually 1 nm or more, in one embodiment 2 nm or more, in one embodiment 3 nm or more, in one embodiment 4 nm or more, and in one embodiment 5 nm or more. Here, the average particle diameter of the nanoparticles can be measured by a dynamic light scattering method (DLS). As the average particle diameter of the nanoparticles in the nanoparticle layer N decreases, the reflection of sunlight at the interface can be further suppressed.

A film thickness of the nanoparticle layer N is usually in a range of 1 nm or more and 500 nm or less, in one embodiment in a range of 1 nm or more and 200 nm or less, and in one embodiment in a range of 20 nm or more and 100 nm or less. The film thickness of the nanoparticle layer N can be measured by observation with a scanning electron microscope (SEM).

### Photoelectric Conversion Layer 4

The description of FIG. 1 will be resumed. The photoelectric conversion layer 4 is a layer located at an intermediate portion of the first carrier transport layer 3a and the second carrier transport layer 3b. The photoelectric conversion layer 4 generates charge carriers by receiving light.

The charge carriers generated in the photoelectric conversion layer 4 move to any one of the first carrier transport layer 3a or the second carrier transport layer 3b.

More specifically, positive charge carriers, that is, holes generated in the photoelectric conversion layer 4 are transported to the first electrode layer 2a or the second electrode layer 2b through a layer corresponding to a hole transport layer among the first carrier transport layer 3a and the second carrier transport layer 3b.

In addition, negative charge carriers, that is, electrons generated in the photoelectric conversion layer 4 are transported to the first electrode layer 2a or the second electrode layer 2b through a layer corresponding to an electron transport layer among the first carrier transport layer 3a and the second carrier transport layer 3b.

The photoelectric conversion layer 4 contains an organic-inorganic perovskite compound, and in one embodiment, the photoelectric conversion layer 4 contains the organic-inorganic perovskite compound as a main component. A content of the organic-inorganic perovskite compound in the photoelectric conversion layer 4 is usually 60% by weight or more, in one embodiment 80% by weight or more, in one embodiment 90% by weight or more, in one embodiment 95% by weight or more, and in one embodiment 100% by weight.

A film thickness of the photoelectric conversion layer is usually in a range of 100 nm or more and 1,000 nm or less, and in one embodiment in a range of 400 nm or more and 700 nm or less.

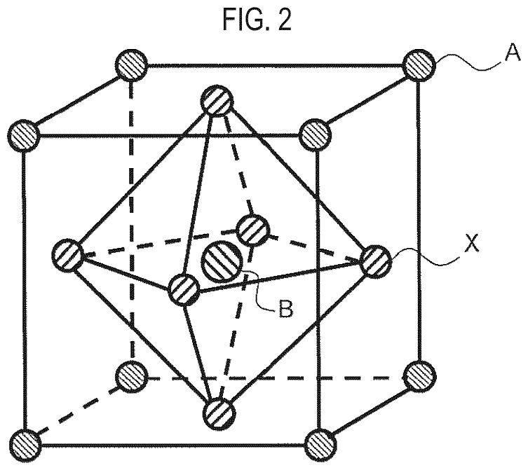

The organic-inorganic perovskite compound is a compound having a perovskite crystal structure. FIG. 2 is a schematic view showing the perovskite crystal structure. As shown in FIG. 2, the perovskite crystal structure has a unit lattice of a cubic crystal system, in which A is disposed at each vertex of a cubic crystal, B is disposed at a body center, and X is disposed at a surface center of the cubic crystal with the body center as a center. The fact that the compound has the perovskite crystal structure can be confirmed by, for example, X-ray diffraction measurement.

The organic-inorganic perovskite compound can be represented by, for example, Formula (1).

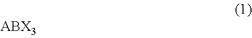

(in the formula, A is a monovalent cation and includes at least one organic cation, B is a divalent cation, and X is a monovalent anion.)

In one embodiment, in Formula (1), A is at least one selected from a monovalent organic ammonium ion and a monovalent amidinium-based ion.

Examples of the monovalent organic ammonium ion include CH₃NH₃⁺ (methylammonium ion; MA), C₂H₅NH₃⁺, C₃H—NH₃⁺, and C₄H₉NH₃⁺.

Examples of the monovalent amidinium-based ion include HC(NH₂)₂⁺ (formamidinium ion; FA).

In one embodiment, in Formula (1), A may further include a monovalent metal ion. Examples of the monovalent metal ion include a rubidium ion (Rb⁺) and a cesium ion (Cs⁺).

In Formula (1), A may be a combination of the monovalent organic ammonium ion, the monovalent amidinium-based ion, and the monovalent metal ion. In one embodiment, in Formula (1), A is MA or FA, or a combination of two selected from the group consisting of MA, FA, and Cs⁺. In one embodiment, in Formula (1), A is a mixed cation of Cs⁺, MA, and FA. In a case where A is a mixed cation, a mixing ratio of each of cations is not limited.

In one embodiment, in Formula (1), B is a divalent metal ion, and is, for example, a lead ion (Pb²⁺), a tin ion (Sn²⁺), or a combination of these ions. In one embodiment, from the viewpoint of improving durability, B is Pb²⁺.

In one embodiment, in Formula (1), X is a halogen ion, and is, for example, at least one selected from a fluoride ion (F⁻), a chloride ion (Cl⁻), a bromide ion (Br⁻), and an iodide ion (I⁻). In one embodiment, in Formula (1), X is at least one selected from Cl⁻, Br⁻, and I⁻. In one embodiment, in Formula (1), X is I⁻.

### First Carrier Transport Layer 3a and Second Carrier Transport Layer 3b

The description of FIG. 1 will be resumed.

The first carrier transport layer 3a receives the charge carriers generated in the photoelectric conversion layer 4, and transports the charge carriers to the first electrode layer 2a. In a case where the first carrier transport layer 3a is a hole transport layer (HTL), the first carrier transport layer 3a transports holes to the first electrode layer 2a. In a case where the first carrier transport layer 3a is an electron transport layer (ETL), the first carrier transport layer 3a transports electrons to the first electrode layer 2a. Detailed description of the hole transport layer and the electron transport layer will be described later.

The second carrier transport layer 3b receives the charge carriers generated in the photoelectric conversion layer 4, and transports the charge carriers to the second electrode layer 2b.

In a case where the second carrier transport layer 3b is a hole transport layer, the second carrier transport layer 3b transports holes to the second electrode layer 2b.

In a case where the second carrier transport layer 3b is an electron transport layer, the second carrier transport layer 3b transports electrons to the second electrode layer 2b.

In a first embodiment, the first carrier transport layer 3a is an electron transport layer and the second carrier transport layer 3b is a hole transport layer. That is, in the first embodiment, the solar cell C according to one aspect of the present disclosure includes a substrate, a cathode, a nanoparticle layer, an electron transport layer, a photoelectric conversion layer, a hole transport layer, and an anode in this order. Alternatively, in the first embodiment, the solar cell C according to one aspect of the present disclosure includes a substrate, a cathode, an electron transport layer, a photoelectric conversion layer, a hole transport layer, a nanoparticle layer, and an anode in this order. Alternatively, in the first embodiment, the solar cell C according to one aspect of the present disclosure includes a substrate, a cathode, a nanoparticle layer, an electron transport layer, a photoelectric conversion layer, a hole transport layer, a nanoparticle layer, and an anode in this order.

Otherwise, in a second embodiment, the first carrier transport layer 3a is a hole transport layer and the second carrier transport layer 3b is an electron transport layer. That is, in the second embodiment, the solar cell C according to one aspect of the present disclosure includes a substrate, an anode, a nanoparticle layer N, a hole transport layer, a photoelectric conversion layer, an electron transport layer, and a cathode in this order. Alternatively, in the second embodiment, the solar cell C according to one aspect of the present disclosure includes a substrate, an anode, a hole transport layer, a photoelectric conversion layer, an electron transport layer, a nanoparticle layer N, and a cathode in this order. Alternatively, in the second embodiment, the solar cell C according to one aspect of the present disclosure includes a substrate, an anode, a nanoparticle layer N, a hole transport layer, a photoelectric conversion layer, an electron transport layer, a nanoparticle layer N, and a cathode in this order.

The hole transport layer has a function of transporting the holes generated by photoelectric conversion in the photoelectric conversion layer to the first electrode layer or the second electrode layer. As a material of the hole transport layer, an organic material or an inorganic material, which is known to be usable in the hole transport layer, can be used.

The organic material that can be used as the material of the hole transport layer is not particularly limited, and examples thereof include 2,2′,7,7′-tetrakis-(N,N-di-4-methoxyphenylamino)-9,9′-spirobifluorene (Spiro-OMeTAD), polyethylene dioxythiophene: polystyrene sulfonate (PEDOT:PSS), poly [bis(4-phenyl) (2,4,6-trimethylphenyl) amine] (PTAA), and 3PATAT-C3 (non-patent document; Journal of The American Chemical Society 2023, Vol. 145, page 7528).

The inorganic material that can be used as the material of the hole transport layer is not particularly limited, and examples thereof include nickel oxide and copper oxide.

In one embodiment, in the above-described first embodiment of the solar cell according to one aspect of the present disclosure, the material of the hole transport layer is one or more selected from the group consisting of Spiro-OMeTAD, PTAA, and nickel oxide.

In one embodiment, in the above-described second embodiment of the solar cell according to one aspect of the present disclosure, the material of the hole transport layer is one or more selected from the group consisting of PEDOT:PSS, PTAA, and nickel oxide.

The electron transport layer has a function of transporting the electrons generated by photoelectric conversion in the photoelectric conversion layer to the first electrode layer or the second electrode layer. As a material of the electron transport layer, an organic material or an inorganic material, which is known to be usable in the electron transport layer, can be used.

The organic material that can be used as the material of the electron transport layer is not particularly limited, and examples thereof include a fullerene compound, a phenanthroline derivative (for example, bathocuproine), and polyethyleneimines. Examples of the fullerene compound include a fullerene (for example, C60 fullerene or C70 fullerene) and a derivative obtained by adding a substituent to the fullerene (for example, [6,6]-phenyl-C61-butyric acid methyl ester (PCBM or also referred to as [60]PCBM) or [6,6]-phenyl-C71-butyric acid methyl ester (PCBM or also referred to as [70]PCBM)).

Examples of the inorganic material that can be used as the material of the electron transport layer include titanium oxide, tin oxide, and zinc oxide.

In one embodiment, in the above-described first embodiment of the solar cell according to one aspect of the present disclosure, the material of the electron transport layer is one or more selected from the group consisting of the fullerene, PCBM, bathocuproine, polyethyleneimine, titanium oxide, and tin oxide.

In one embodiment, in the above-described second embodiment of the solar cell according to one aspect of the present disclosure, the material of the electron transport layer is one or more selected from the group consisting of the fullerene, PCBM, bathocuproine, and polyethyleneimine.

### First Electrode Layer 2a and Second Electrode Layer 2b

The first electrode layer 2a is an electrode in contact with the first carrier transport layer 3a. In a case where the first carrier transport layer 3a is a hole transport layer, the first electrode layer 2a is an anode; and in a case where the first carrier transport layer 3a is an electron transport layer, the first electrode layer 2a is a cathode. In addition, the second electrode layer 2b is an electrode in contact with the second carrier transport layer 3b. In a case where the second carrier transport layer 3b is a hole transport layer, the second electrode layer 2b is an anode; and in a case where the second carrier transport layer 3b is an electron transport layer, the second electrode layer 2b is a cathode.

As materials of the first electrode layer and the second electrode layer, known materials as electrodes of a solar cell can be used, for example, metal materials, such as aluminum (Al), silver (Ag), and gold (Au), transparent conductive films, such as indium tin oxide (ITO), indium zinc oxide (IZO), aluminum-doped zinc oxide (AZO), and fluorine-doped tin oxide (FTO), carbon nanotubes, and the like. In a case where the first electrode layer and the second electrode layer are in contact with the nanoparticle layer N, the materials of the first electrode layer and the second electrode layer are materials of the transparent electrode layer.

In a case where the first electrode layer and/or the second electrode layer is a transparent electrode layer, as a material of the transparent electrode layer, a transparent conductive film, such as ITO, IZO, AZO, and FTO, can be used.

In one embodiment, the materials of the first electrode layer and the second electrode layer are ITO, IZO, and FTO.

### Substrate 1

The substrate 1 is a plate-shaped or film-shaped member, and supports the first electrode layer 2a, the nanoparticle layer N, the first carrier transport layer 3a, the photoelectric conversion layer 4, the second carrier transport layer 3b, and the second electrode layer 2b.

A material of the substrate 1 is not particularly limited, and examples thereof include an inorganic material such as glass, an organic material such as polyethylene, polyethylene terephthalate, polyethylene naphthalate, polyimide, polyamide, polyamideimide, a liquid crystal polymer, and a cycloolefin polymer, and a metal material such as stainless steel and silicon.

The substrate 1 may be transparent or opaque. In a case where light is incident from a surface of the substrate, a transparent substrate is used. As the transparent substrate, a substrate including glass, polyethylene terephthalate, polyethylene naphthalate, polyimide, polyamide, polyamideimide, or a cycloolefin polymer can be used. Meanwhile, in a case where light is incident from a side opposite to the substrate, the substrate can be opaque.

The solar cell according to one aspect of the present disclosure can be used alone, or in combination with other solar cells such as a silicon (Si) solar cell. In a case of being used in combination with other solar cells, for example, the solar cell according to one aspect of the present disclosure can be a tandem-type solar cell in which other solar cells are laminated on a side of the second electrode layer (counter electrode of the substrate) in the solar cell according to one aspect of the present disclosure.

### Method of Manufacturing Solar Cell

Next, the method of manufacturing a solar cell, that is, the manufacturing method according to one aspect of the present disclosure will be described in more detail.

In the manufacturing method according to the present embodiment, the solar cell is manufactured by forming, on the substrate 1, films of the transparent electrode layer as the first electrode layer 2a, the nanoparticle layer N, the first carrier transport layer 3a, the photoelectric conversion layer 4, the second carrier transport layer 3b, and the transparent electrode layer as the second electrode layer 2b in this order; by forming, on the substrate 1, films of the first electrode layer 2a, the first carrier transport layer 3a, the photoelectric conversion layer 4, the second carrier transport layer 3b, the nanoparticle layer N, and the transparent electrode layer as the second electrode layer 2b in this order; or by forming, on the substrate 1, films of the transparent electrode layer as the first electrode layer 2a, the nanoparticle layer N, the first carrier transport layer 3a, the photoelectric conversion layer 4, the second carrier transport layer 3b, the nanoparticle layer N, and the transparent electrode layer as the second electrode layer 2b in this order. The manufacturing method according to the present embodiment is characterized in that a dispersion liquid containing nanoparticles including the same material that is transparent and conductive as the transparent electrode layer as the first electrode layer 2a and/or the second electrode layer 2b is applied onto a surface in contact with the transparent electrode layer as the first electrode layer 2a and/or the second electrode layer 2b (in a case of the first electrode layer 2a, a surface opposite to a surface in contact with the substrate) to form the nanoparticle layer N; and a film forming step of the other portions can adopt the same method as that of a photoelectric conversion element (solar cell) in the related art.

Therefore, one embodiment of the present disclosure is a method of manufacturing a solar cell including a step of forming the first carrier transport layer on the first electrode layer of the substrate including the first electrode layer, a step of forming, on the first carrier transport layer, the photoelectric conversion layer that contains an organic-inorganic perovskite compound as a main component, a step of forming the second carrier transport layer on the photoelectric conversion layer, and a step of forming the second electrode layer on the second carrier transport layer, in which the substrate is a transparent substrate, in a case where the first electrode layer is a transparent electrode layer, the method further includes, before the step of forming the first carrier transport layer, a step of forming the nanoparticle layer by applying, onto the transparent electrode layer, the dispersion liquid that contains nanoparticles including the same material as the transparent electrode layer, and in a case where the second electrode layer is a transparent electrode layer, the method further includes, between the step of forming the second carrier transport layer on the photoelectric conversion layer and the step of forming the second electrode layer on the second carrier transport layer, a step of forming the nanoparticle layer by applying, onto the second carrier transport layer, the dispersion liquid that contains nanoparticles including the same material as the transparent electrode layer. In the embodiment, in a case where the first electrode layer is a transparent electrode layer, the first carrier transport layer may be a hole transport layer and the second carrier transport layer may be an electron transport layer; in a case where the second electrode layer is a transparent electrode layer, the second carrier transport layer may be a hole transport layer and the first carrier transport layer may be an electron transport layer; and in a case where both the first electrode layer and the second electrode layer are transparent electrode layers, one of the first carrier transport layer and the second carrier transport layer may be a hole transport layer and the other may be an electron transport layer.

The application of the dispersion liquid containing the nanoparticles onto the first electrode layer 2a and/or the second carrier transport layer 3b can be performed by a known method. The method of applying the dispersion liquid containing the nanoparticles is not particularly limited, and examples thereof include a spin coating method, an ink jet method, a spray method, a blade coating method, and a die coating method.

The application of the dispersion liquid containing the nanoparticles can be usually performed in a range of 15° C. or higher and 35° C. or lower in the atmosphere.

The nanoparticles are not limited as long as they are the same material as the material that is transparent and conductive, the material being used for the transparent electrode layer as the first electrode layer 2a and/or the second electrode layer 2b. In one embodiment, an average particle diameter of the nanoparticles in the nanoparticle layer Nis usually 500 nm or less, in one embodiment 400 nm or less, in one embodiment 300 nm or less, in one embodiment 200 nm or less, in one embodiment 100 nm or less, in one embodiment 80 nm or less, in one embodiment 60 nm or less, in one embodiment 40 nm or less, and in one embodiment 20 nm or less. The lower limit value of the average particle diameter of the nanoparticles in the nanoparticle layer N is not limited. The average particle diameter of the nanoparticles in the nanoparticle layer N is usually 1 nm or more, in one embodiment 2 nm or more, in one embodiment 3 nm or more, in one embodiment 4 nm or more, and in one embodiment 5 nm or more. Here, the average particle diameter of the nanoparticles can be measured by a dynamic light scattering method (DLS). As the average particle diameter of the nanoparticles in the nanoparticle layer N decreases, the reflection of sunlight at the interface can be further suppressed.

A concentration of the nanoparticles in the dispersion liquid containing the nanoparticles is not particularly limited, but is usually 2% by weight or less and in one embodiment 1.5% by weight or less with respect to the total weight of the dispersion liquid. By setting the concentration of the nanoparticles to the above-described concentration, the reflection of incident sunlight can be suppressed, and thus the transmission of the sunlight to the photoelectric conversion layer in the solar cell and the absorption of the sunlight by the photoelectric conversion layer can be improved.

A solvent of the dispersion liquid containing the nanoparticles is an alcohol, for example, isopropyl alcohol (iPA). By using an alcohol as the solvent of the dispersion liquid containing the nanoparticles, deterioration of the photoelectric conversion layer or the carrier transport layer can be suppressed.

A film thickness of the nanoparticle layer is adjusted to be usually in a range of 1 nm or more and 500 nm or less, in one embodiment in a range of 1 nm or more and 200 nm or less, and in one embodiment in a range of 20 nm or more and 100 nm or less. The film thickness of the nanoparticle layer can be measured by observation with a scanning electron microscope (SEM).

The manufacturing method according to one aspect of the present disclosure can include a step of drying the applied dispersion liquid containing the nanoparticles. The drying step can be usually performed by heating in a range of 80° C. or higher and 150° C. or lower in the atmosphere.

In the manufacturing method according to one aspect of the present disclosure, layers other than the nanoparticle layer can be formed by a known film forming method.

Hereinafter, the one aspect of the present disclosure will be described in more detail by an embodiment. However, the technical scope of one aspect of the present disclosure is not limited to the embodiment.

As the substrate, a laminate (30 mm×30 mm) in which an indium tin oxide (ITO) film (transparent electrode layer used as an electrode layer that is a transparent conductive film) processed by photolithography was laminated on a glass plate was used. As the hole transport layer, 3PATAT-C3 was used. As the dispersion liquid for forming the nanoparticle layer, an ITO nanoparticle dispersion liquid (average particle diameter by DLS: less than 100 nm) was used. As the perovskite, CsI, MABr, FAI, PbI₂, or PbBr₂ was used. As the electron transport layer, [6,6]-phenyl-C61-butyric acid methyl ester (PCBM) was used.

In the experimental procedure, a UV ozone treatment was carried out as a surface treatment. The subsequent operations were carried out in a glove box (N₂ atmosphere).

### Formation of Hole Transport Layer

A DMF solution of 0.1 mM of 3PATAT-C3 was filtered through a filter before application, and formed into a film by a spin coating method, and then subjected to an annealing treatment at 110° C.

### Formation of Nanoparticle Layer

The ITO nanoparticle dispersion liquid was diluted with dehydrated iPA, and formed into a film by a spin coating method after adjusting the concentration, and then subjected to an annealing treatment at 110° C. The concentration adjustment was carried out such that the concentration of the ITO nanoparticles was 0% by weight (without the nanoparticle layer), 0.05% by weight, 0.2% by weight, 0.4% by weight, 0.6% by weight, 0.8% by weight, 1% by weight, 1.5% by weight, 2% by weight, 3% by weight, or 4% by weight with respect to the total weight of the diluted dispersion liquid; and the results are shown depending on the concentration used.

### Formation of Perovskite Layer

A solution of 1.2 M of Cs_{0.05}FA_{0.79}MA_{0.16}Pb₁I_{2.55}Br_{0.45} (numerical value is a molar ratio) of DMF/DMSO=80/20% by volume was filtered through a filter before application, and then formed into a film by a spin coating method, chlorobenzene as a poor solvent was added dropwise thereto during the rotation, and the film was subjected to an annealing treatment at 110° C.

### Formation of Electron Transport Layer

A dehydrated 2-propanol solution of 25 mg/ml of PCBM was filtered through a filter before application, and then formed into a film by a spin coating method.

### Formation of Electrode Layer

Ag (100 nm) was formed into a film by vacuum vapor deposition of patterning with a metal mask.

### Comparative Example

A perovskite solar cell was produced by forming, on the ITO film of the substrate, the films of the hole transport layer, the nanoparticle layer, the perovskite layer, the electron transport layer, and the electrode layer in this order.

### EXAMPLE

A perovskite solar cell was produced by forming, on the ITO film of the substrate, the films of the nanoparticle layer, the hole transport layer, the perovskite layer, the electron transport layer, and the electrode layer in this order.

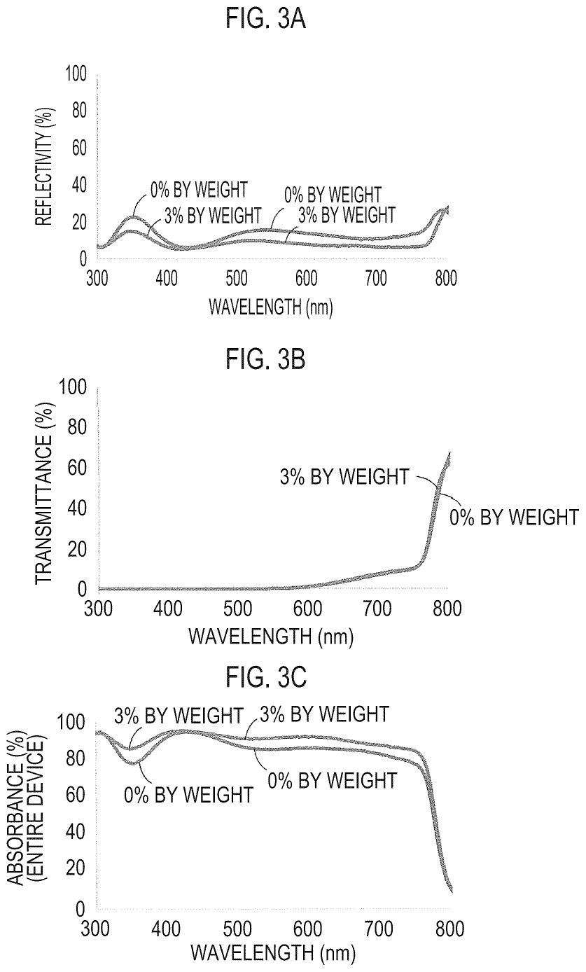

FIGS. 3A to 3C show a reflectivity (FIG. 3A), a transmittance (FIG. 3B), and an absorbance (FIG. 3C) of light with respect to incident light in the perovskite solar cell of Comparative Example. FIGS. 3A to 3C show results regarding 0% by weight and 3% by weight. From FIGS. 3A to 3C, it was found that the reflectivity can be reduced by the ITO nanoparticles. It was found that, as the concentration of the ITO nanoparticles increased, the reflectivity tended to decrease.

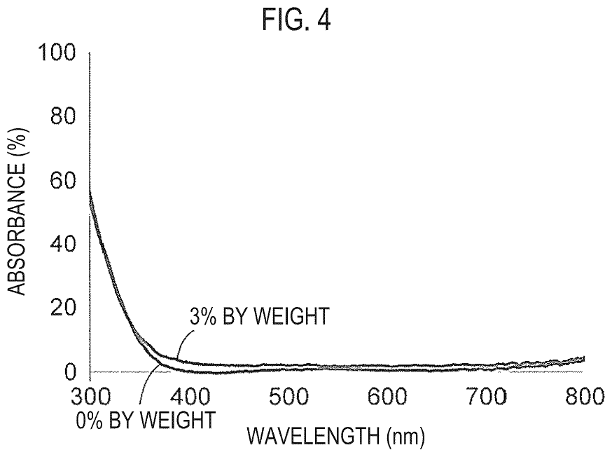

FIG. 4 shows an absorbance of light with respect to incident light in the laminate in which the nanoparticle layer and the hole transport layer were formed, on the ITO film of the substrate, into films in this order. From FIG. 4, it was found that there was absorption of the ITO nanoparticles in a wavelength range of 350 nm or more and 500 nm or less. It was found that, as the concentration of the ITO nanoparticles increased, the absorption tended to increase.

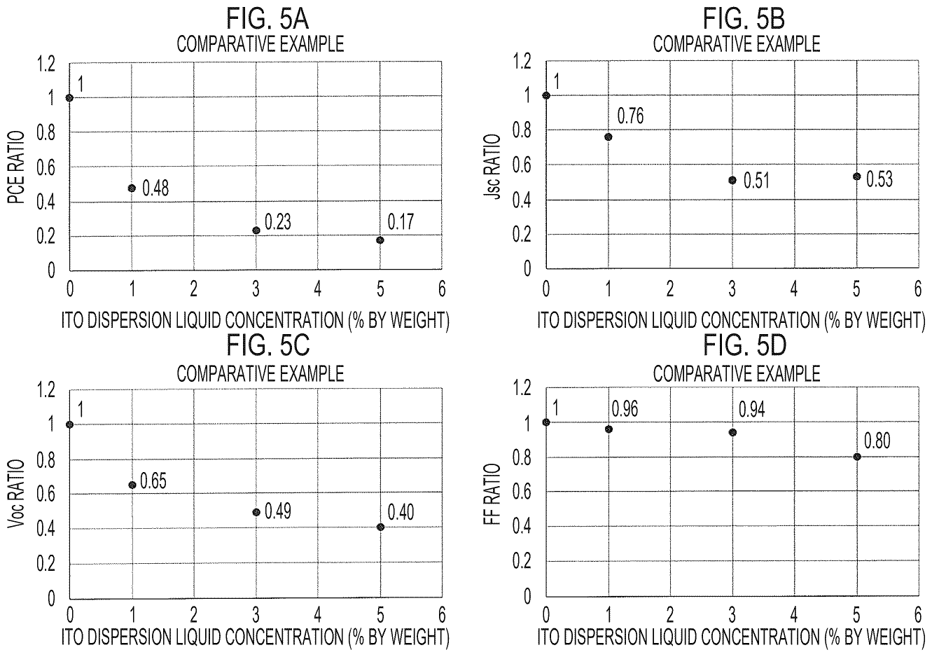

FIGS. 5A to 5D show IV evaluation results (PCE (FIG. 5A), Jsc (FIG. 5B), Voc (FIG. 5C), and FF (FIG. 5D)) of the perovskite solar cell of Comparative Example. From FIGS. 5A to 5D, it was found that all characteristic values were deteriorated in the perovskite solar cell of Comparative Example.

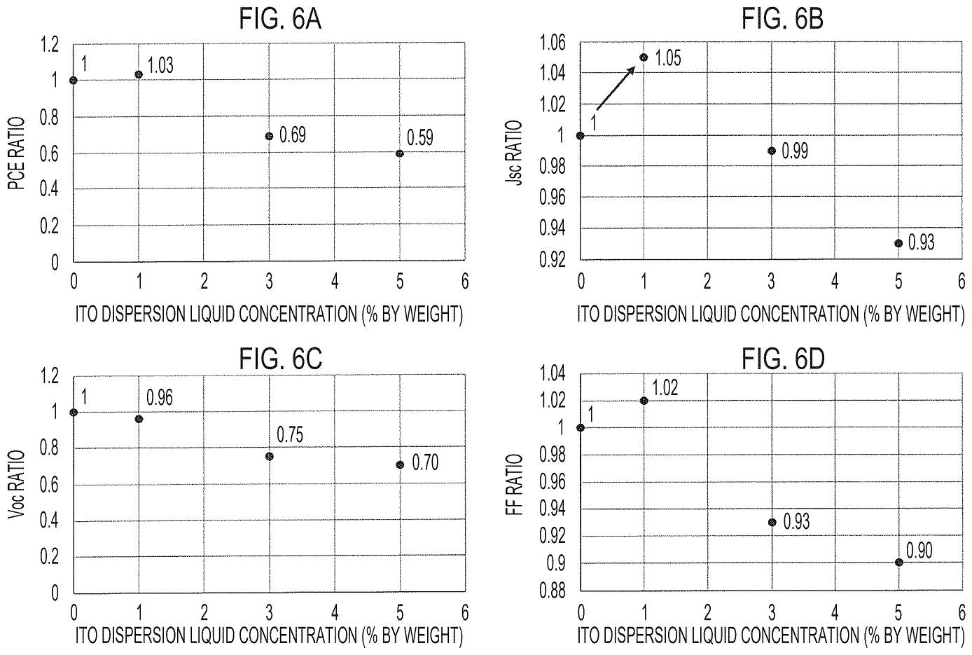

FIGS. 6A to 6D show IV evaluation results (PCE (FIG. 6A), Jsc (FIG. 6B), Voc (FIG. 6C), and FF (FIG. 6D)) of the perovskite solar cell of Example. From FIGS. 6A to 6D, it was found that Jsc was improved in the perovskite solar cell of Example.

What is claimed is:

1. A method of manufacturing a solar cell, the method comprising:
forming a first carrier transport layer on a first electrode layer of a substrate including the first electrode layer;
forming, on the first carrier transport layer, a photoelectric conversion layer that contains an organic-inorganic perovskite compound as a main component;
forming a second carrier transport layer on the photoelectric conversion layer; and
forming a second electrode layer on the second carrier transport layer,
wherein the substrate is a transparent substrate,
wherein, in a case where the first electrode layer is a transparent electrode layer, the method further includes, before the forming the first carrier transport layer, forming a nanoparticle layer by applying, onto the transparent electrode layer, a dispersion liquid that contains nanoparticles including the same material as the transparent electrode layer, and
wherein, in a case where the second electrode layer is a transparent electrode layer, the method further includes, between the forming the second carrier transport layer on the photoelectric conversion layer and the forming the second electrode layer on the second carrier transport layer, forming a nanoparticle layer by applying, onto the second carrier transport layer, a dispersion liquid that contains nanoparticles including the same material as the transparent electrode layer.

2. The method according to claim 1,
wherein the transparent electrode layer includes ITO, and
wherein an ITO concentration in the dispersion liquid is 2.0% by weight or less with respect to a total weight of the dispersion liquid.

3. The method according to claim 1,
wherein, in the case where the first electrode layer is a transparent electrode layer, the first carrier transport layer is a hole transport layer and the second carrier transport layer is an electron transport layer,
wherein, in the case where the second electrode layer is a transparent electrode layer, the second carrier transport layer is a hole transport layer and the first carrier transport layer is an electron transport layer, and
wherein, in a case where both the first electrode layer and the second electrode layer are transparent electrode layers, one of the first carrier transport layer and the second carrier transport layer is a hole transport layer and the other is an electron transport layer.

4. A perovskite solar cell comprising:
a substrate;
a first electrode layer on the substrate;
a first carrier transport layer on the first electrode layer;
a photoelectric conversion layer on the first carrier transport layer, the photoelectric conversion layer containing an organic-inorganic perovskite compound as a main component;
a second carrier transport layer on the photoelectric conversion layer; and
a second electrode layer on the second carrier transport layer,
wherein the substrate is a transparent substrate,
wherein, in a case where the first electrode layer is a transparent electrode layer, the perovskite solar cell further includes, between the first electrode layer and the first carrier transport layer, a nanoparticle layer including the same material as the transparent electrode layer, and
wherein, in a case where the second electrode layer is a transparent electrode layer, the perovskite solar cell further includes, between the second carrier transport layer and the second electrode layer, a nanoparticle layer including the same material as the transparent electrode layer.

5. The perovskite solar cell according to claim 4,
wherein, in the case where the first electrode layer is a transparent electrode layer, the first carrier transport layer is a hole transport layer and the second carrier transport layer is an electron transport layer,
wherein, in the case where the second electrode layer is a transparent electrode layer, the second carrier transport layer is a hole transport layer and the first carrier transport layer is an electron transport layer, and
wherein, in a case where both the first electrode layer and the second electrode layer are transparent electrode layers, one of the first carrier transport layer and the second carrier transport layer is a hole transport layer and the other is an electron transport layer.
